(19) United States
(12) Patent Application Publication
(10) Pub. No.: US 2012/0032350 A1
(43) Pub. Date: Feb. 9, 2012

(54) Systems and Methods for Heat Dissipation Using Thermal Conduits

(75) Inventors: Robert W. Warren, Newport Beach, CA (US); Jianjun Li, Holmdel, NJ (US); Nic Rossi, Causeway (HK)

(73) Assignee: CONEXANT SYSTEMS, INC., Newport Beach, CA (US)

(21) Appl. No.: 12/852,353

(22) Filed: Aug. 6, 2010

(51) Int. Cl. H01L 23/34; H01L 21/50

(52) U.S. Cl. 257/782; 438/122; 257/E23.08; 257/E21.499

(57) ABSTRACT

The addition of thermal conduits by bonding bond wires to bond pads either in a wire loop configuration or a pillar configuration can improve thermal dissipation of a fabricated die. The thermal conduits can be added as part of the normal packaging process of a semiconductor die and are electrically decoupled from the circuitry fabricated on the fabricated die. In an alternative, a dummy die is affixed to the fabricated die and the thermal conduits are affixed to the dummy die. Additionally, thermal conduits can be used in conjunction with a heat spreader.

### BACKGROUND OF THE INVENTION

1. Field of the Invention

The present invention relates generally to thermal dissipation in a semiconductor package and more specifically to the use of thermal conduits affixed to bond pads within the semiconductor package.

2. Related Art

Heat dissipation is essential in semiconductor chips. In the extreme, if a semiconductor chip is allowed to get too hot it can damage the chip. Even outside of this extreme, semiconductor chips are designed to operate within a particular temperature range. In order to maintain a chip within its operating temperature range, heat must be drawn away from the chip. As chips become higher performance, they pose a greater challenge as they consume more power and generate more heat.

Methods traditionally used to address the heat dissipation problem include adding heat spreaders to the package, using higher thermal conductivity mold compounds, increasing the package layer count or size, or using higher thermal conductivity die attach epoxies. In some extreme cases the die size is increased to improve the heat dissipation. However, these attempts are very costly and impact negatively product margin, plus they have proven to affect device reliability.

### SUMMARY OF INVENTION

Embodiments of the invention apply to a variety of semiconductor package types including bond wired ball grid array (BGA) package, a flip-chipped BGA package, a cavity down BGA package, a dual in-line package (DIP) package, a pin grid array (PGA) package, a leadless chip carrier (LCC) package, a small-outline integrated circuit (SOIC) package, a plastic leaded chip carrier (PLCC) package, a plastic quad flat pack (PQFP) package, a thin quad flat pack (TQFP) package, a thin small-outline packages (TSOP) package, a land grid array (LGA) package or a Quad-Flat No-lead (QFN) package.

In one embodiment, a package comprises a semiconductor die fabricated with additional bond pads for the coupling of thermal conduits. Wire bonds functioning as thermal conduits are bonded to the additional bond pads. These wire bonds can be connected in a variety of configurations including a wire loop configuration or a pillar configuration. In the former case, both ends of a wire bond are connected to two bond pads forming a loop. In the latter case, one end of a wire bond is connected to a single bond pad and the wire bond is left substantially normal to the substrate.

In one embodiment, an encapsulating mold compound encases the entire package including the thermal conduits. In another embodiment, some or all of the thermal conduits are left exposed outside the mold compound. In yet another embodiment, a heat spreader is included in the package and the heat spreader can optionally be in contact with the thermal conduits.

In other embodiments, a dummy die is attached to the fabricated semiconductor die and the thermal conduits are attached to the dummy die instead of the fabricated die.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is a cross sectional view of an embodiment of a bond wired BGA package;

FIG. 2A is a cross sectional view of a semiconductor package, packaged in accordance with one embodiment of the invention;

FIG. 2B is a top view of the semiconductor package;

FIG. 3 is a cross sectional view of another embodiment of a semiconductor package;

FIG. 4 is a cross sectional view of an embodiment of a semiconductor package with an internal heat spreader;

FIG. 5 is a cross sectional view of an embodiment of a semiconductor package with an internal heat spreader;

FIG. 6A is a cross sectional view of an embodiment of a semiconductor package using a pillar thermal conduct design;

FIG. 6B is a top view of an embodiment of a semiconductor package using a pillar thermal conduct design;

FIG. 7 is a cross sectional view of another embodiment of a semiconductor package using the pillar design;

FIG. 8 is a cross sectional view of an embodiment of a semiconductor package with pillar designed thermal conduits and an internal heat spreader;

FIG. 9 is a cross sectional view of another embodiment of a semiconductor package with an internal heat spreader;

FIG. 10 is a cross sectional view of a embodiment of a semiconductor package with a dummy die;

FIG. 11 is a cross sectional view of another embodiment of a semiconductor package with a dummy die and exposed thermal conduits;

FIG. 12 is a cross sectional view of a embodiment of a semiconductor package with a dummy die and a heat spreader;

FIG. 13 is a cross sectional view of another embodiment of a semiconductor package with a dummy die and a heat spreader;

FIG. 14 is a cross sectional view of a embodiment of a semiconductor package using a pillar thermal conduit design with a dummy die;

FIG. 15 is a cross sectional view of another embodiment of a semiconductor package using a pillar thermal conduit design with a dummy die and exposed thermal conduits;

FIG. 16 is a cross sectional view of a embodiment of a semiconductor package using a pillar thermal conduit design with a dummy die and a heat spreader; and

FIG. 17 is a cross sectional view of another embodiment of a semiconductor package using a pillar thermal conduit design with a dummy die and a heat spreader.

### DETAILED DESCRIPTION

A detailed description of embodiments of the present invention is presented below. While the disclosure will be described in connection with these drawings, there is no intent to limit it to the embodiment or embodiments disclosed herein. On the contrary, the intent is to cover all alternatives, modifications and equivalents included within the spirit and scope of the disclosure.

It should be emphasized that though the embodiments described below are given in terms of BGA packaging and more specifically wire bonded BGA packaging. It can apply to other types of packaging including but not limited to flip-chipped BGA packaging, cavity down BGA packaging, dual in-line package (DIP) packaging, pin grid array (PGA) packaging, leadless chip carrier (LCC) packaging, small-outline integrated circuit (SOIC) packaging, plastic leaded chip carrier (PLCC) packaging, plastic quad flat pack (PQFP) packaging, thin quad flat pack (TQFP) packaging, thin small-outline packages (TSOP) packaging, land grid array (LGA) packaging and Quad-Flat No-lead (QFN) packaging.

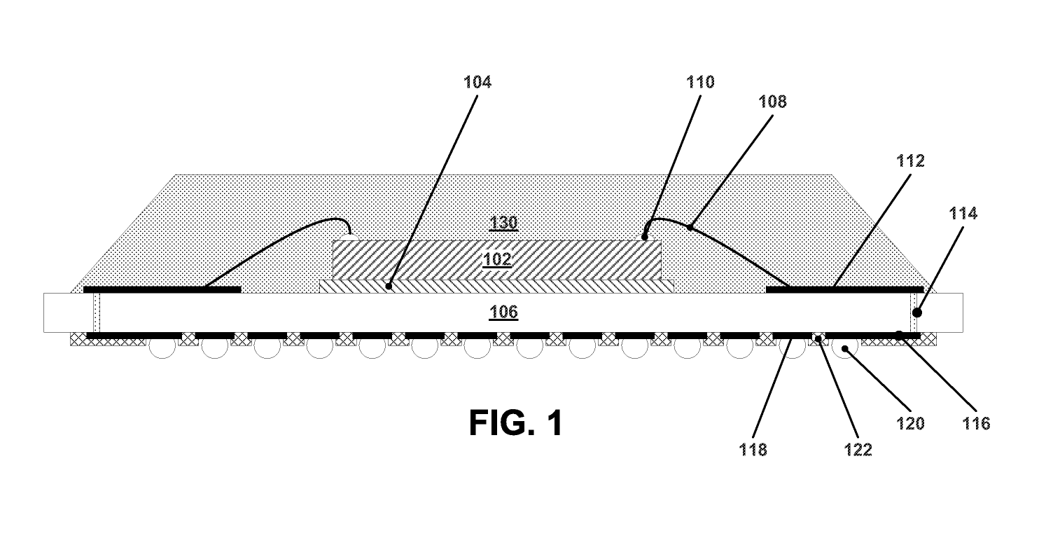

FIG. 1 is a cross sectional view of an embodiment of a bond wired BGA package. Fabricated die 102 is attached with die attach 104 to substrate 106. Electrically, fabricated die 102 is accessed through bond wire 108 (sometimes referred to as a wirebond) through bond pad 110. Bond wire 108 is connected to substrate 106 through a metal trace such as metal trace 112. In some packages, substrate 106 could comprise multiple layers and contain additional metal traces for routing, as in this illustration. Metal trace 112 is connected through via 114 to a bond finger such as metal trace 116. Metal traces on the bottom of the substrate such as metal trace 116 comprises a solder pad such as solder pad 118 where a solder ball such as solder ball 120 can be attached at the factory. Solder mask 122 covers the metal traces on the bottom of the substrate but leaves openings exposing the solder pads. Mold compound 130 fills in the package.

Typically, the vias such as via 114 are drilled into the substrate and a metal or conductor is coated along the wall of the via to maintain electrical contact between metal trace 112 and metal trace 116. For this purpose it is not necessary to completely fill the via with a conductor.

In the BGA packaging, solder pads represent a type of interface pad. Some interface pads such as solder pad 118 are electrically coupled to a metal trace in the printed circuit board where electronic signals or electricity can pass between die 102 and other components. Other interface pads are sometimes used to thermally couple the package to the printed circuit board.

A portion of the heat from the top of fabricated die is 102 drawn away through the bond pads such as bond pad 110 through bond wires such as bond wire 108 and ultimately out the interface whether it is out through the mold compound or through a solder ball in a BGA package. This heat dissipation due to the bond wires does draw heat away from the fabricated die. With the cost reducing trend of using copper wire rather than gold wire for the bond wires, an added benefit of improved thermal conduction results. In fact, copper wire is approximately 26% better thermal conduction than gold wire.

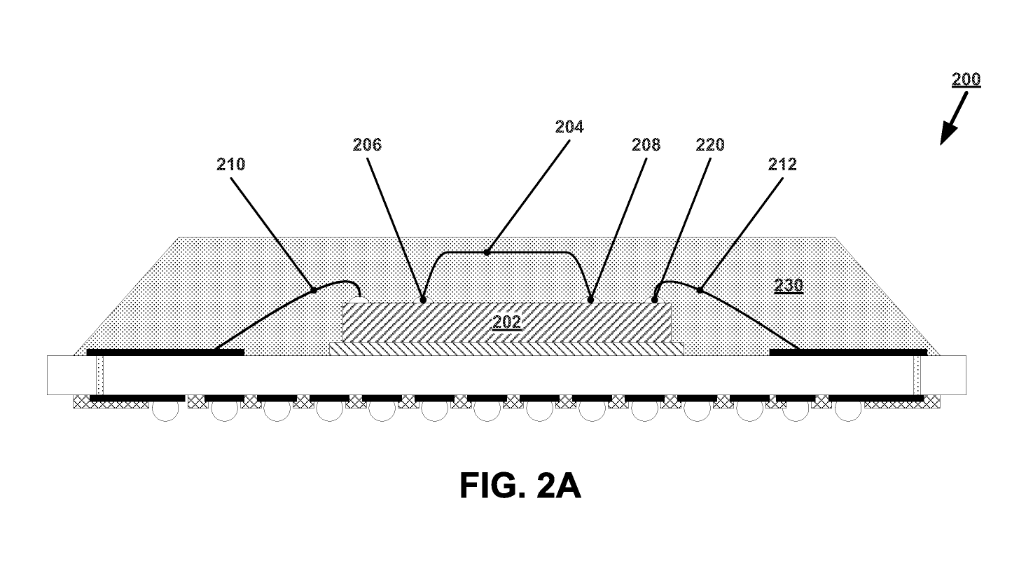

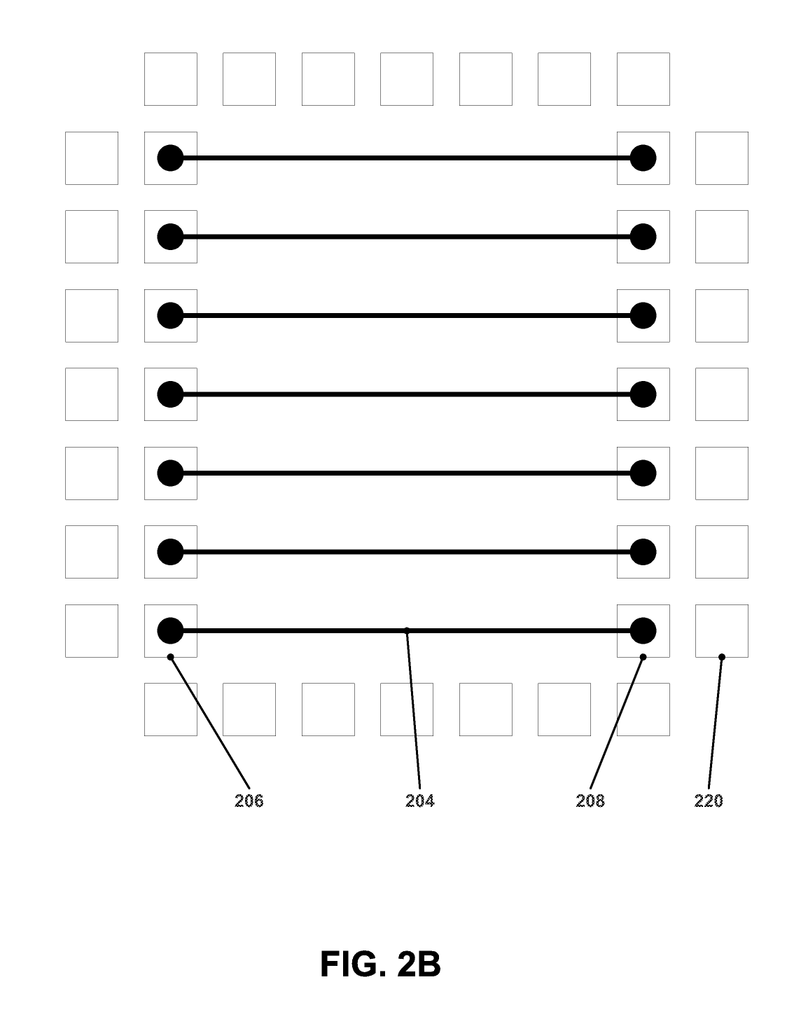

FIG. 2A is a cross sectional view of semiconductor package 200, packaged in accordance with one embodiment of the invention, in addition to the usual bond wires 210 and 212 attached to fabricated die 202 via bond pads (e.g., bond pad 220), bond wires represented by bond wire 204 is attached between bond pads represented by bond pads 206 and 208. Though the both ends of bond wire 204 are connected to fabricated die 202, bond wire 204 serves as a thermal conduit, that is a wire or contact attached to a die which is not necessarily electrically coupled to any circuitry on the die, and draws heat away from fabricated die 202 where it can be dissipated into mold compound 230. Bond pad 200 is an example of a bond pad used for electrical coupling purposes. This effectively removes the heat from the die, thus reduces the package's thermal resistance so that the package can dissipate more power. FIG. 2B is a top view of semiconductor package 200. To match the example shown in FIG. 2A, bond wire 204 is shown connected between two exemplary bond pads, bond pads 206 and 208. The bond pads on the perimeter, such as bond pad 220 are bond pads provided for the electrical coupling of the fabricated die to the electrical interface (e.g., solder balls).

The packaging process is essentially the same as the packaging process for a semiconductor die without thermal conduits. Typically, a semiconductor die is connected to a substrate with a die attach. Then bond wires are attached to the bond pad and metal traces on the substrate. Finally, the package is encased in a mold compound, often performed by a process such as injection molding. To include the thermal conduits, bond wires can be attached to the appropriate bond pads as part of the same wire bonding step used to connected bond wires to the bond pads during the step. As a result, the thermal conduits can easily be added using existing techniques and equipment and with minimal additional cost or processing time.

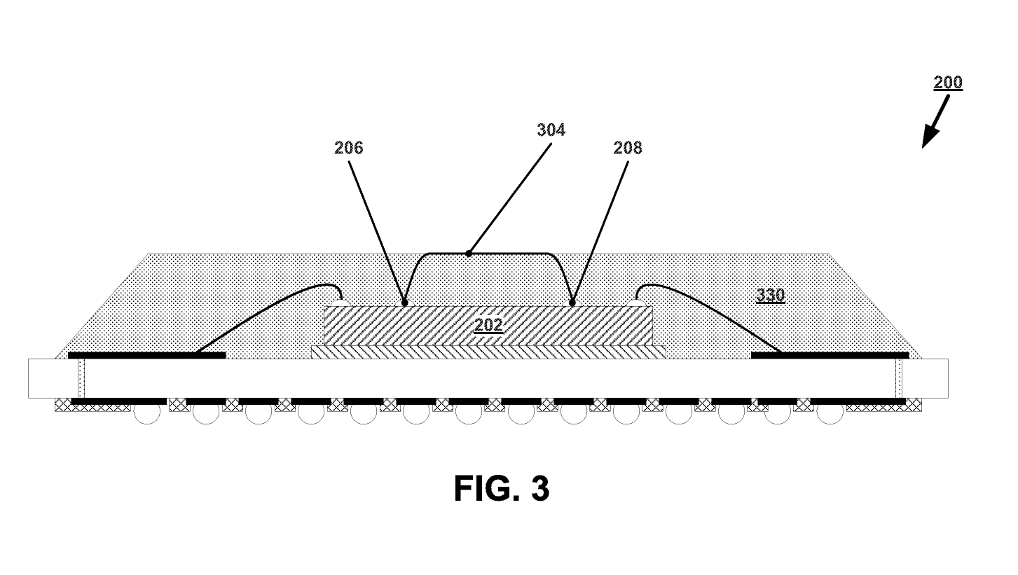

FIG. 3 is a cross sectional view of another embodiment of a semiconductor package. Package 300 is similar to semiconductor package 200 with the addition of thermal conduits created by adding bond wire 304 connected to bond pads 206 and 208. The difference is that bond wire 304 is exposed at the surface of mold compound 330. By exposing the thermal conduits, heat can either be dissipated to the atmosphere or to an external heat sink attached to the surface of the package, thereby further improving heat dissipation. With respect to the packaging process, the thermal conduits can be left exposed either as-molded or by stripping the molding down after the molding process for example by using micro-ablation.

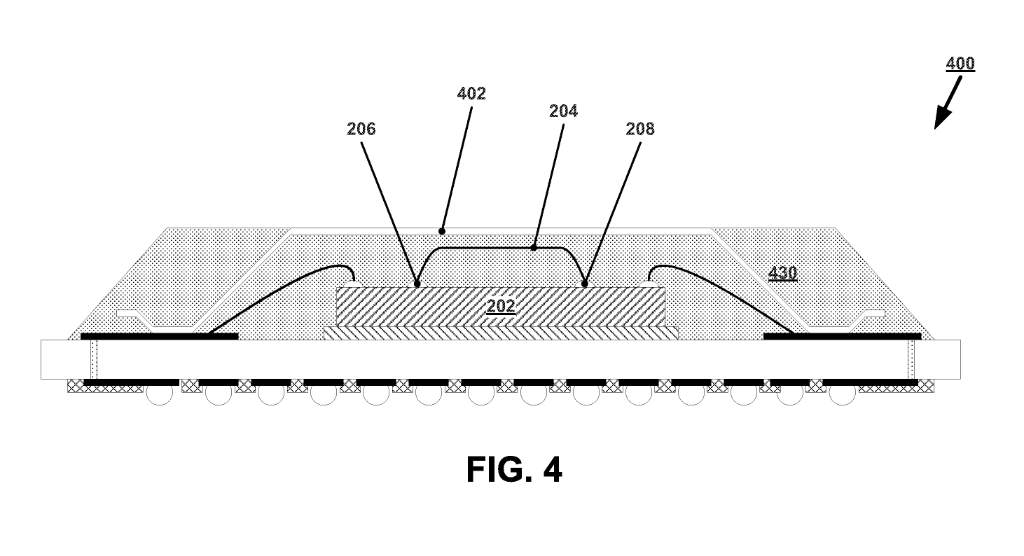

FIG. 4 is a cross sectional view of an embodiment of a semiconductor package with an internal heat spreader. Package 400 is similar to package 200 except package 400 includes heat spreader 402. In this particular example, the thermal conduits such as bond wire 204, draws heat closer to heat spreader 402 which improves overall heat dissipation. Because the thermal conduits are closer to the heat spreader, heat drawn by the thermal conduits has less mold compound to traverse to reach the heat spreader. The heat spreader can further be thermally coupled to a ground plane or to thermal interfaces such as thermal balls (solder balls used for thermal dissipation usually located under the die). Specifically, the base of the heat spreader can be attached to metal traces and vias that route the heat to either the ground plane or thermal interfaces. With respect to process, the heat spreader is attached then mold compound 430 is applied to encapsulate the wire bonds and the device.

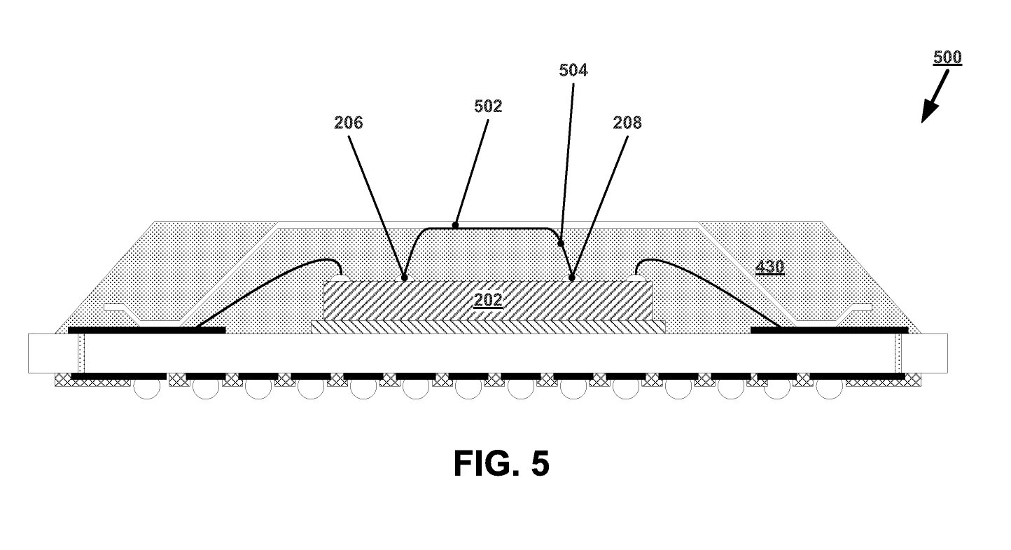

FIG. 5 is a cross sectional view of an embodiment of a semiconductor package with an internal heat spreader. Package 500 is similar to package 400 except the thermal conduits such as bond wire 504 are in contact with heat spreader 502. By making direct contact, heat drawn from the top of fabricated die 202 is conducted directly to heat spreader 504. In terms of the packaging process, the thermal conduits when bonded to their bond pads form a wire loop. Prior to encapsulation, if the wire loops are tall enough, the heat spreader can compress them slightly when being attached. In this way contact between the most or all of the thermal conduits and the heat spreader can be insured. Afterwards, the standard encapsulation process can take place.

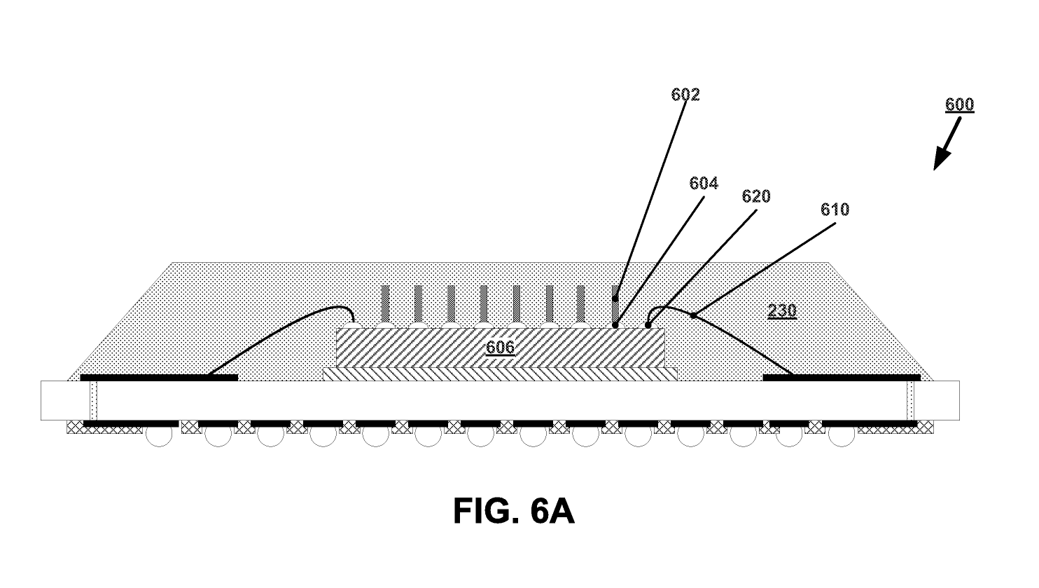

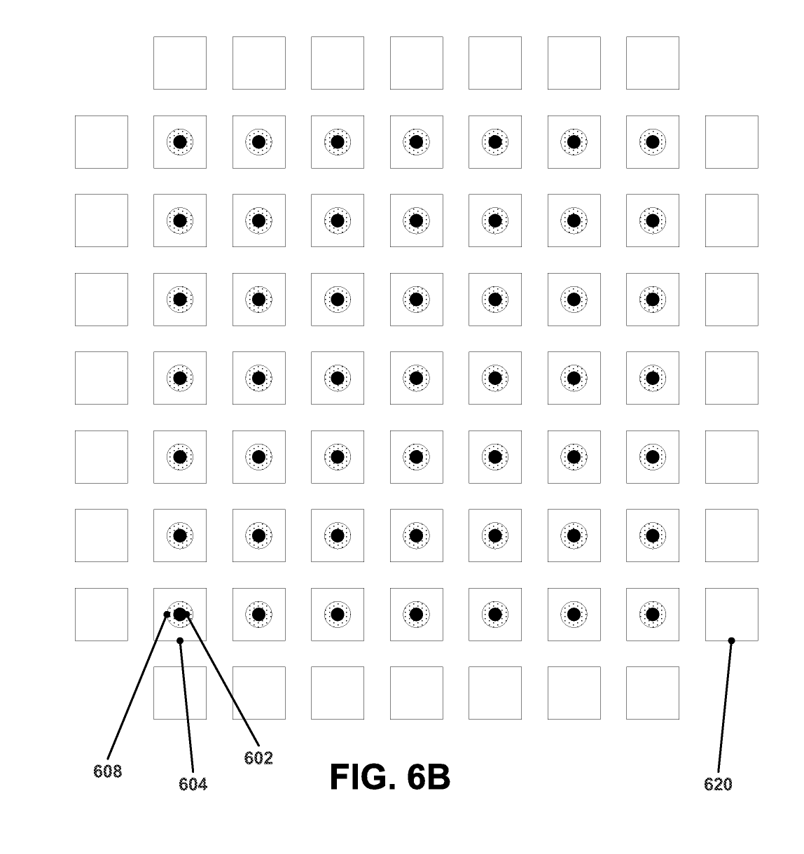

As an alternative to the wire loop design of the thermal conduits, a pillar design can be employed. FIG. 6A is a cross sectional view of an embodiment of a semiconductor package using a pillar thermal conduit design. Like package 200, package 600 has bond wires (e.g. bond wire 602) bonded to bond pads (e.g. 604) on fabricated die 606. Unlike package 200, each bond wire used as a thermal conduit is bonded to only one bond pad. Because these thermal conduits are mounted in the vertical direction (a direction normal to the substrate/semiconductor die), more conduits can be added. In addition, examples of traditional electrical bond wires are shown as bond wire 610 bonded to bond pad 620. The thermal conduits (e.g., bond wire 602) and their corresponding bond pads (e.g., bond pad 604) are arranged in an array. Because a tighter spacing is possible with the pillar design a higher density of thermal conduits can be placed on top of a fabricated die. The same packaging process can be applied to a pillar configuration as to a wire loop configuration. However, vertical bond wires are more susceptible to sweeping during the packaging process especially during the molding process. To counteract this sweeping a thicker bond wire can be used. Mild sweeping is not generally problematic. Even if the thermal conduit wires touch, they pose no problems. However, if the wires are allowed to bend over too far, they may not provide enough thermal conduction from the fabricated die or worse yet they may come in contact with the bond wires used for electrical signals, possibly shorting them out. In addition, severe sweeping may cause excessive stress at the bond and cause the bond pad or die to crack. The amount of sweeping is also related to the length of wire. A long wire is more susceptible sweeping than a short wire. In the extreme, a ball stub can be all that is deposited on the bond pad. But even such short wires show significant thermal benefits.

During a ball bonding process, the most common wire bond process, a wire is fed through a capillary and melted into a ball, so that the wire has a ball at the end. The ball is placed on the bond pad and using electrical, thermal and/or ultrasonic energy, the ball is bonded to the bond pad. The residual ball after bonding is sometimes referred to as the ball stub. This is also shown in FIG. 6B by the example of ball stub 608

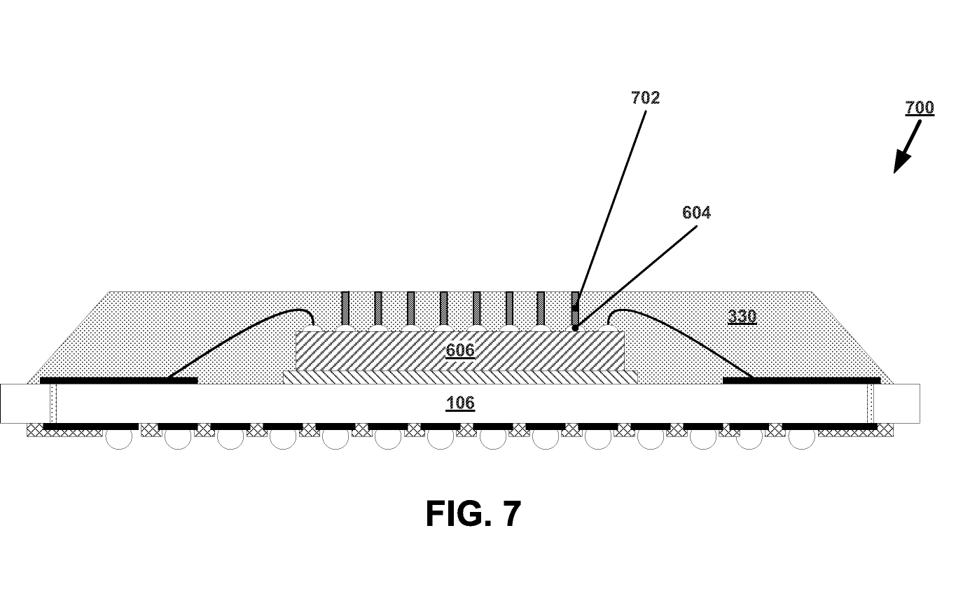

FIG. 7 is a cross sectional view of another embodiment of a semiconductor package using the pillar design. Analogous to semiconductor package 300 for wire loop thermal conduit design, semiconductor package 700 has thermal conduits (e.g., bond wire 702) that are exposed at the surface of the package. Like package 300, the thermal conduits in package 700 can be left exposed either as-molded or by stripping the encapsulating molding down after the molding process for example by using micro-ablation.

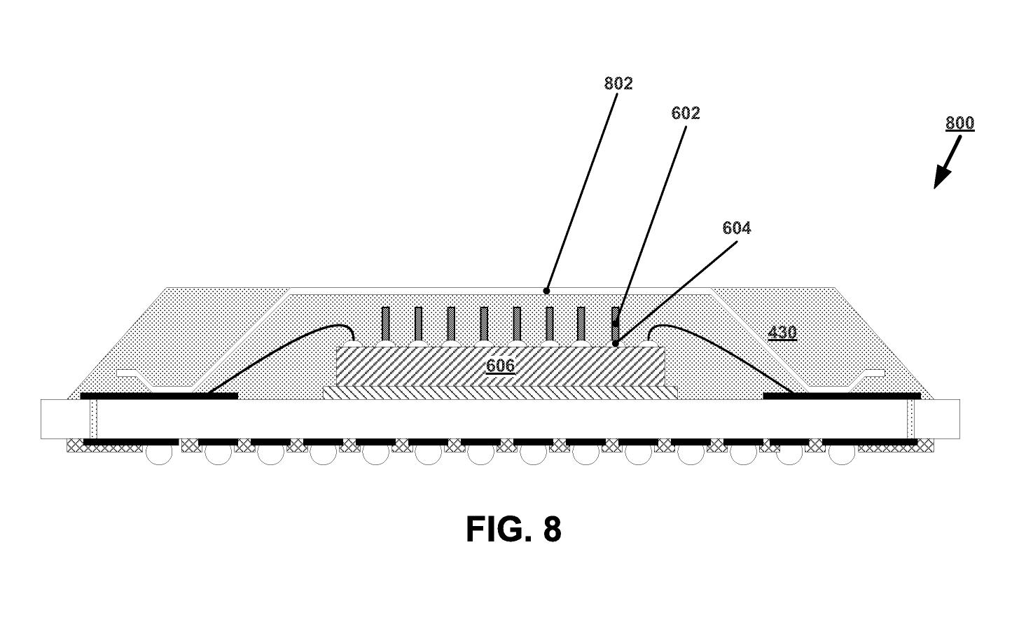

FIG. 8 is a cross sectional view of an embodiment of a semiconductor package with pillar designed thermal conduits and an internal heat spreader. Package 800 is similar to package 400 except package 800 has thermal conduits in the pillar configuration. In this particular example, the thermal conduits such as bond wire 604, draws heat closer to heat spreader 802 which improves overall heat dissipation.

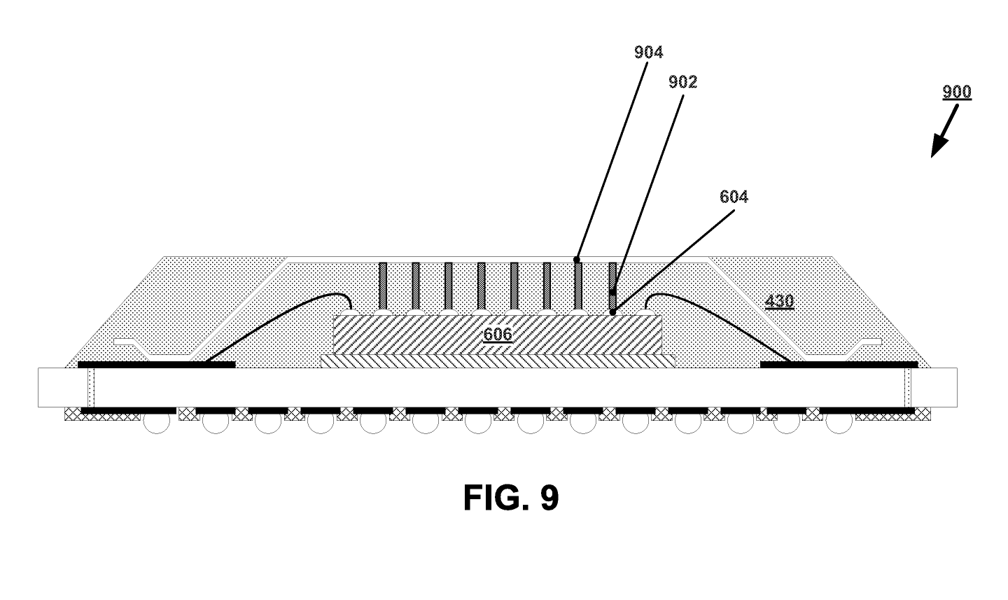

FIG. 9 is a cross sectional view of another embodiment of a semiconductor package with an internal heat spreader. Package 900 is similar to package 500 except the thermal conduits are in a pillar configuration. In this example, the thermal conduits such as bond wire 902 are in contact with heat spreader 904. By making direct contact, heat drawn from the top of fabricated die 606 is conducted directly to heat spreader 904. Because of the pillar configuration, placing heat spreader on top of the thermal conduits is more difficult, because in this configuration, the thermal conduits do not naturally flex as they do in the case of a wire loop configuration. The length of the bond wires would have to be more tightly controlled to insure uniformity. A small amount of sweeping would have to be allowed to accommodate the any remaining non-uniformity in the bond wire lengths.

One constraint placed on the aforementioned packages and packaging techniques is that the fabricated semiconductor die ideally should supply bond pads. Typically, on a fabricated semiconductor die, a passivation layer is deposited only exposing the bond pads. All other underlying metallization is not exposed. This means that the bond pads need to be incorporated into the design of the fabricated die.

An alternative to the having bond pad designed into the semiconductor die is to affix a dummy die to the surface of the semiconductor die. Methods for affixing a dummy die are disclosed in U.S. patent application Ser. No. 12/365,101, filed on Feb. 3, 2009 and is incorporated by reference herewith.

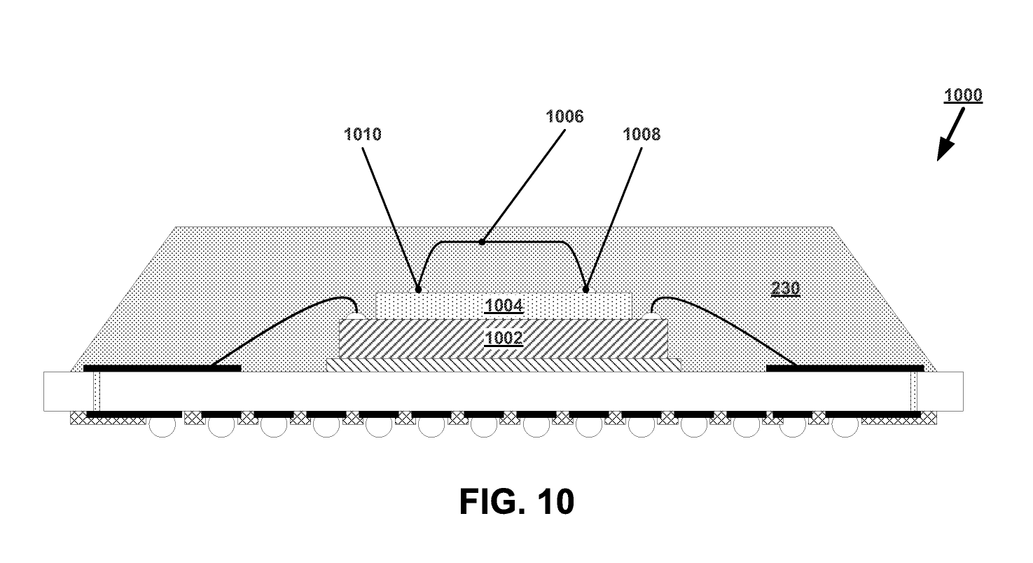

FIG. 10 is a cross sectional view of another embodiment of a package analogous to the package 200, but with a dummy die. Dummy die 1004 is affixed to fabricated die 1002 and bond wires such as bond wire 1006 is affixed to bond pads provided by dummy die 1004 such as bond pads 1008 and 1010 to form thermal conduits in the wire-loop configuration. Unlike fabricated dies 202 or 606, fabricated die 1002 does not have to have extra bond pads designed on it to accommodate the thermal conduits.

Dummy die 1002 can be a piece of metalized dummy silicon which is inexpensive and easily obtained from a foundry. Furthermore, metalized dummy silicon is commonplace because it is often used as a test chip. The metalized silicon can simply have a metallization layer exposed on one surface in effect forming one large bond pad without a passivation layer on top. Since the bond wires are used solely as thermal conduits, there is no need for the bond pads or bond wires to be electrically isolated; as a result the bond pads can be merged into a single metallization layer. In addition this metallization layer can span across the entire die, further enhancing thermal dissipation. In fact, the metallization layer can be made thicker which not only enhances thermal dissipation but eliminates cracking issues which can happen in a fabricated die. Sometimes when wire bonding, the bond pad or die can crack due to the heat and stresses applied during the bonding process. However, a thicker metallization layer can eliminate this issue when using a dummy die.

An alternative is that dummy die 1004 can be a “recycled” die. Specifically, dummy die 1004 can be a die rejected during wafer testing where “bad” dies are identified. Functionally, the rejected dies do not work or are anticipated to fail. These dies are typically discarded. However, as a dummy die, they are well suited since they are already equipped with bond pads which are well suited for the wire loop configuration of thermal conduits. The only constraint is that the dummy die should be smaller than the fabricated die.

Whether a piece of metalized silicon or a recycled waste die, the dummy die draws heat away from the surface of the fabricated semiconductor die and to the thermal conduits affixed to the top surface of the dummy die.

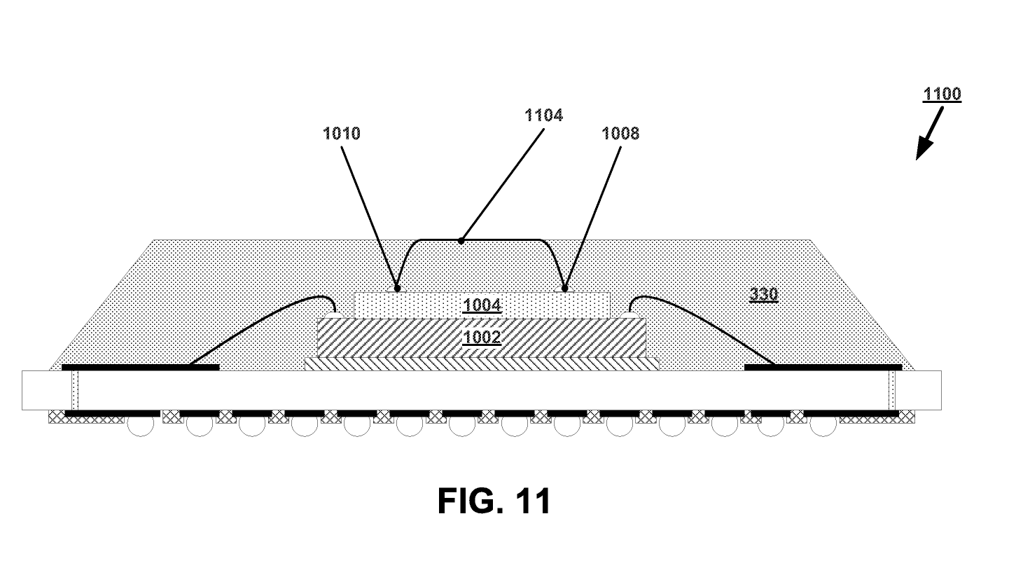

Analogously, a dummy die can be used similarly to the various package configurations mentioned above. Specifically, FIG. 11 is a cross sectional view of an embodiment of a semiconductor package analogous to package 300. Dummy die 1004 is affixed atop fabricated semiconductor die 1002 and thermal conduits are created by adding bond wires (e.g. bond wire 1104) connected to bond pads on dummy die 1004, (e.g., bond pads 1008 and 1010). The thermal conduits are left exposed.

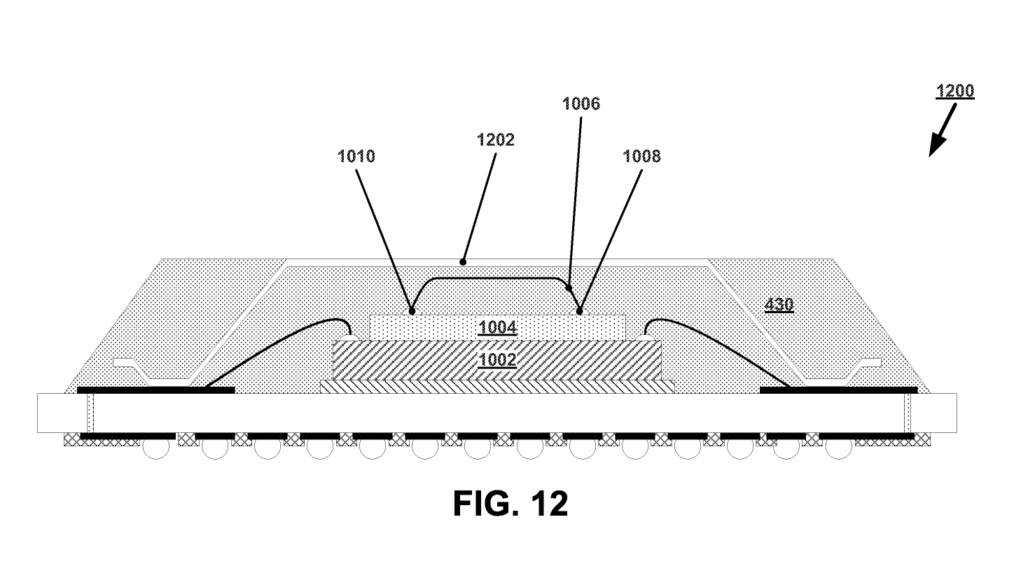

FIG. 12 is a cross sectional view of an embodiment of a package analogous to package 400. Package 1200 is similar to package 1000 but includes heat spreader 1202. In this particular example, the thermal conduits such as bond wire 1006, draws heat closer to heat spreader 1202 which improves overall heat dissipation. Because the thermal conduits are closer to the heat spreader, heat drawn by the thermal conduits has less mold compound to traverse to reach the heat spreader.

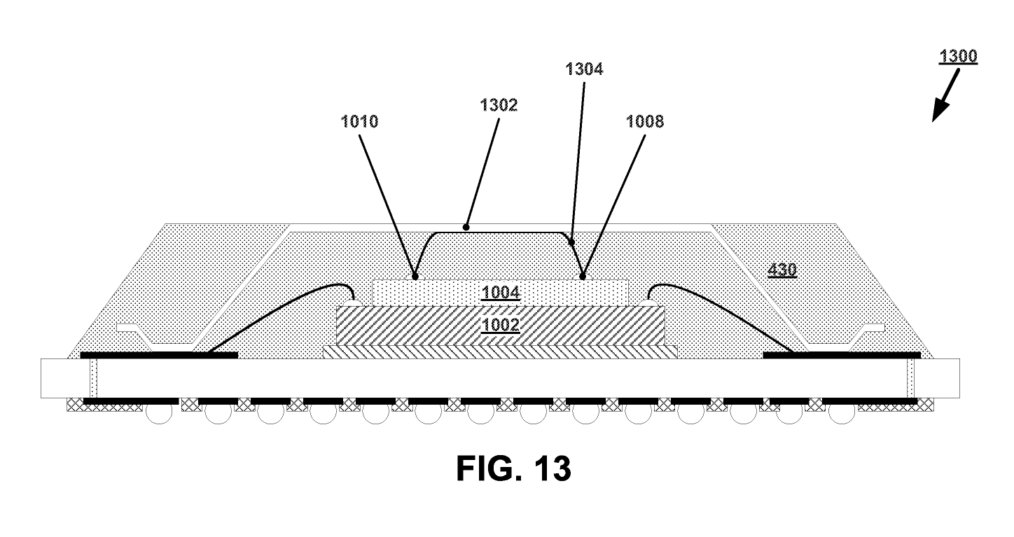

FIG. 13 is a cross sectional view of a package analogous to package 400. Package 1300 is similar to package 1200 except the thermal conduits such as bond wire 1304 are in contact with heat spreader 1302. By making direct contact, heat drawn from the top of fabricated die 1002 through dummy die 1004 and is conducted directly to heat spreader 1302.

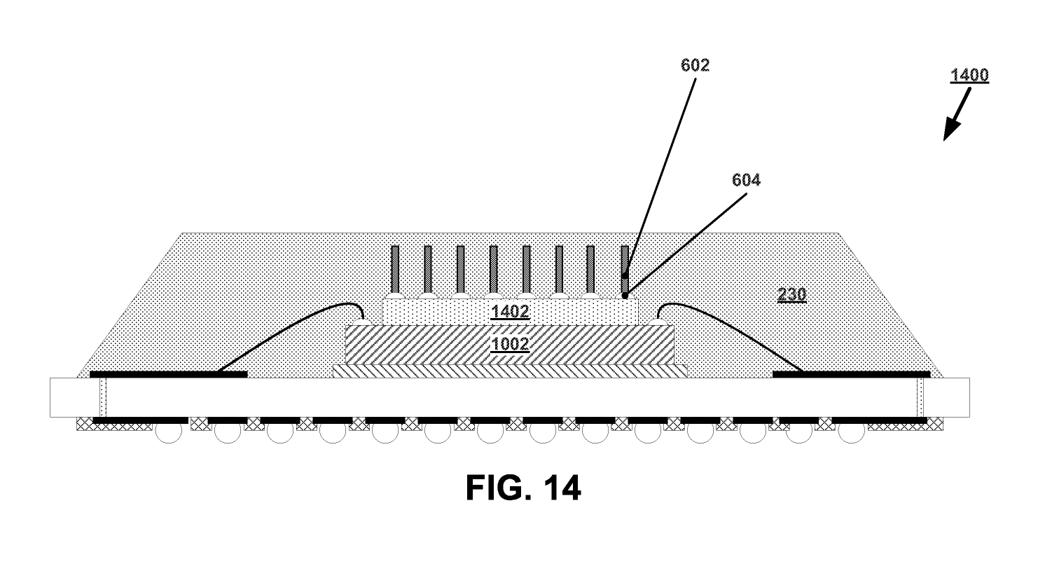

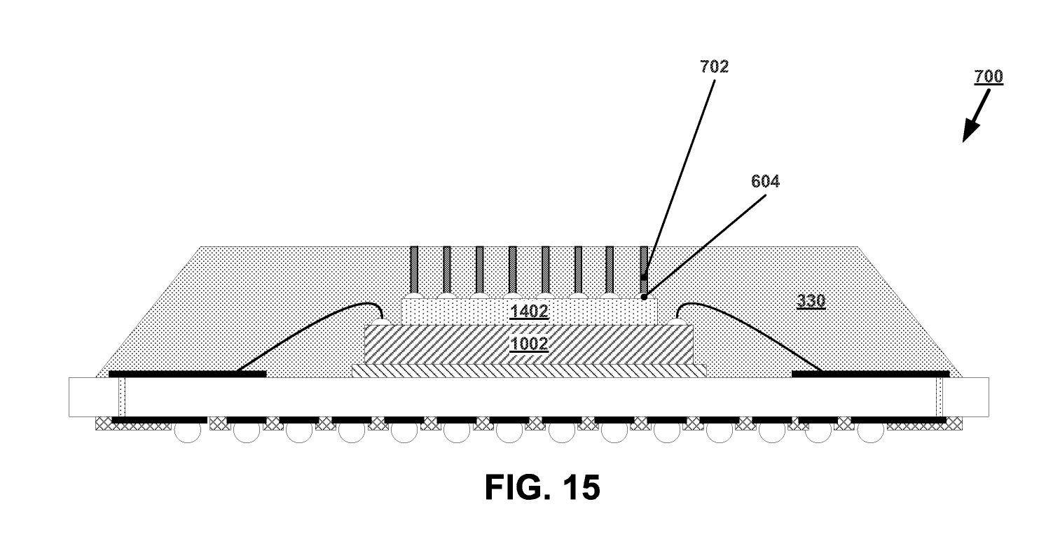

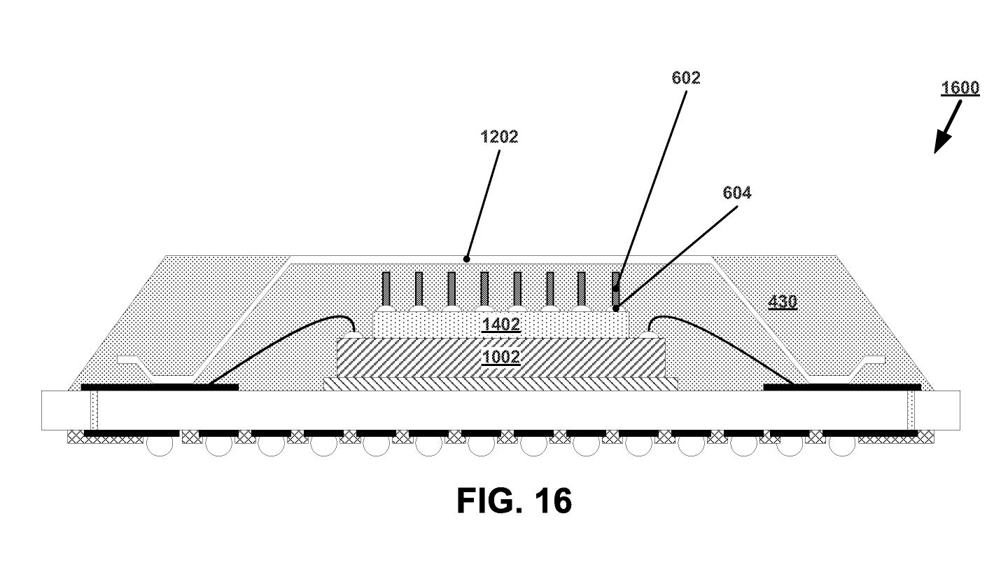

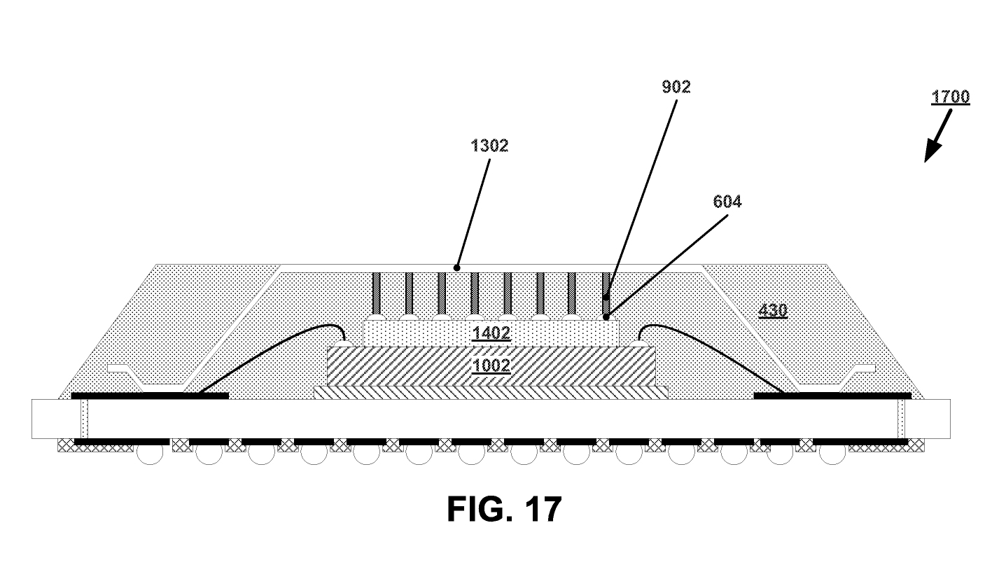

FIGS. 14, 15, 16, and 17 are cross sectional views of packages analogous to packages 1000, 1100, 1200, and 1300, respectively. They differ from their respective package analogues because thermal conduits are formed by bond wires (e.g., bond wire 1404) that are attached in a pillar configuration to bond pads (e.g., bond pad 1406) provided by dummy die 1402. Additionally packages 1400, 1500, 1600, and 1700 are analogous to package counterparts 600, 700, 800, and 900 but with the addition of die 1402 affixed on top of fabricated die 1002 and thermal conduits bonded to the dummy die. Dummy die 1402 may differ from dummy die 1004 because a different bond pad pattern may be required however if the dummy die is a metalized silicon with a single exposed metal layer than the same dummy die can be used in either configuration.

The material used for the thermal conduits can be any material normally used as metal in semiconductor fabrication or packaging. The most common substances are copper, gold, silver or aluminum. Of the group, aluminum is cheapest, but offers the least thermal conductivity. Gold and silver are the most expensive and offer better thermal conductivity. Copper offers the best thermal conductivity, but is more difficult to work with than gold, because of the higher melting temperature and because copper lacks the inertness of gold. The use of copper often requires packaging under an inert atmosphere to avoid oxidation. Generally speaking, the use of the same type of material as used for the electrical bond wires is probably the most practical choice.

It should be emphasized that the above-described embodiments are merely examples of possible implementations. Many variations and modifications may be made to the above-described embodiments without departing from the principles of the present disclosure. For example, the technique can be applied to other packaging types already enumerated above. In addition, the thermal conduits can be added in any combination (e.g., with or without heat spreader, pillar or wire loop configuration, with or without dummy dies) to multiple die packages. All such modifications and variations are intended to be included herein within the scope of this disclosure and protected by the following claims.

What is claimed:

1. A semiconductor package comprising:
a fabricated semiconductor die attached to a substrate and having a plurality of bond pads;
a plurality of thermal conduits, each formed from a bond wire bonded to one of the plurality of bond pad; and
an encapsulating mold compound.

2. The semiconductor package of claim 1, wherein a portion of at least one of the plurality of thermal conduits is left exposed by the encapsulating mold compound.

3. The semiconductor package of claim 1 wherein each of the plurality of thermal conduits are bonded on one end and oriented in a direction essentially normal to the substrate.

4. The semiconductor package of claim 1 wherein each of the plurality of thermal conduits are bonded at both ends, each end to one of the plurality of bond pads.

5. The semiconductor package of claim 1 further comprising a heat spreader.

6. The semiconductor package of claim 5 wherein at least one of the plurality of thermal conduits is in physical contact with the heat spreader.

7. The semiconductor package of claim 1 wherein each of the bond wires comprises copper, gold, silver, aluminum or a combination thereof.

8. The semiconductor package of claim 1 wherein the semiconductor package is a cavity up, bond wired ball grid array (BGA) package, a flip-chipped BGA package, a cavity down BGA package, a dual in-line package (DIP) package, a pin grid array (PGA) package, a leadless chip carrier (LCC) package, a small-outline integrated circuit (SOIC) package, a plastic leaded chip carrier (PLCC) package, a plastic quad flat pack (PQFP) package, a thin quad flat pack (TQFP) package, a thin small-outline packages (TSOP) package, a land grid array (LGA) package or a Quad-Flat No-lead (QFN) package.

9. A semiconductor package comprising:
a fabricated semiconductor die attached to a substrate;
a dummy die attached to the fabricated semiconductor die, said dummy die having at least one bond pad;
a plurality of thermal conduits, each formed from a bond wire bonded to the at least one bond pad; and
an encapsulating mold compound.

10. The semiconductor package of claim 9, wherein a portion of at least one of the plurality of thermal conduits is left exposed by the encapsulating mold compound.

11. The semiconductor package of claim 9 wherein each of the plurality of thermal conduits are bonded on one end and oriented in essentially the vertical direction.

12. The semiconductor package of claim 9 wherein each of the plurality of thermal conduits are bonded at both ends, each end to a bond pad.

13. The semiconductor package of claim 9 further comprising a heat spreader.

14. The semiconductor package of claim 13 wherein at least one of the plurality of thermal conduits is in physical contact with the heat spreader.

15. The semiconductor package of claim 9 wherein the dummy die is a recycled fabricated semiconductor die.

16. The semiconductor package of claim 9 wherein the dummy die is metalized silicon having a single metalized surface as the bond pad.

17. The semiconductor package of claim 9 wherein each of the bond wires comprises copper, gold, silver, aluminum or a combination thereof.

18. The semiconductor package of claim 9 wherein the semiconductor package is a cavity up, bond wired BGA package, a flip-chipped BGA package, a cavity down BGA package, a DIP package, a PGA package, a LCC package, a SOIC package, a PLCC package, a PQFP package, a TQFP package, a TSOP package, a LGA package or a QFN package.

19. A method of packaging a semiconductor die comprising:
attaching the semiconductor die to a substrate;
creating a thermal conduit by bonding a bond wire to a bond pad;
encapsulating the package in a mold compound.

20. The method of claim 17, wherein the encapsulating leaves a portion of the thermal conduit exposed.

21. The method of claim 17, wherein the thermal conduit is bonded on one end and oriented in a direction essentially normal to the substrate.

22. The method of claim 17, wherein the thermal conduit is bonded at both ends, each end a bond pad.

23. The method of claim 17, further comprising attaching a heat spreader.

24. The method of claim 23, wherein the thermal conduit is in physical contact with the heat spreader.

25. The method of claim 17, further comprising attaching a dummy die to the fabricated semiconductor die.

26. The method of claim 17, wherein the dummy die is a recycled fabricated semiconductor die.

27. The method of claim 17, wherein the dummy die is metalized silicon having a single metalized surface as the bond pad.
